(19) United States
(12) Patent Application Publication
(10) Pub. No.: US 2012/0153277 A1
(43) Pub. Date: Jun. 21, 2012

(54) CHANNEL-ETCH TYPE THIN FILM TRANSISTOR AND METHOD OF MANUFACTURING THE SAME

(75) Inventors: Seiichiro Yaginuma, Tokyo (JP); Tatsuya Iwasaki, Machida-shi (JP); Ryo Hayashi, Yokohama-shi (JP); Hideya Kumomi, Tokyo (JP); Masaya Watanabe, Hachioji-shi (JP)

(73) Assignee: CANON KABUSHIKI KAISHA, Tokyo (JP)

(21) Appl. No.: 13/326,859

(22) Filed: Dec. 15, 2011

(30) Foreign Application Priority Data
Dec. 20, 2010 (JP) 2010-282814
Nov. 8, 2011 (JP) 2011-244061

(51) Int. Cl. H01L 29/786; H01L 21/34

(52) U.S. Cl. 257/43; 438/104; 257/E29.296; 257/E21.46

(57) ABSTRACT

A channel layer is formed on a substrate by using an oxide semiconductor and then a sacrificial layer of an oxide containing In, Zn and Ga and representing an etching rate greater than the etching rate of the oxide semiconductor is formed on the channel layer. Thereafter, a source electrode and a drain electrode are formed on the sacrificial layer and the sacrificial layer exposed between the source electrode and the drain electrode is removed by means of wet etching.

### BACKGROUND OF THE INVENTION

1. Field of the Invention

The present invention relates to a channel-etch type thin film transistor using an oxide semiconductor and a method of manufacturing the same. More particularly, the present invention relates to a thin film transistor having a structure formed by removing part of the channel layer that is damaged by dry etching for forming a drain electrode and a source electrode and a method of manufacturing such a thin film transistor.

2. Related Background Art

Liquid crystal displays and organic EL displays using thin film transistors (TFTs) as drive elements have been put into practical use in recent years. While amorphous Si and polycrystalline Si are mainly employed for semiconductor layers of such TFTs, researches are intensively being made on semiconductor materials other than Si. Instances of using amorphous oxides containing In, Ga and Zn (In—Ga—Zn—O) for semiconductor layers of TFTs have been reported recently. Such amorphous oxide TFTs provide advantages including that they can be prepared by way of low temperature process and that a large display area can be realized with ease by using such TFTs.

While there are various TFT structures, amorphous Si-TFTs having a channel-etch structure are being popularly employed as TFTs for large screen displays. A channel-etch structure is a structure obtained by depositing an electrode material on a semiconductor layer that becomes a channel layer and subsequently forming a source electrode and a drain electrode by patterning, using a dry etching technique. To date, high performance channel-etch type TFTs in which stability consists with uniformity cannot be produced without difficulty as amorphous oxide TFTs containing In—Ga—Zn—O as described below. For this reason, channel protection type (or etch-stopper type) TFTs that have a protection layer on the channel region are in the main stream. Regardless of semiconductor material, channel protection type is structurally more complex than channel-etch type and entails a higher manufacturing cost. Therefore, there is a demand for channel-etch type amorphous oxide TFTs similar to amorphous Si-TFTs.

When preparing a channel-etch type TFT, using a semiconductor layer made of an amorphous oxide of In—Ga—Zn—O, the semiconductor layer is exposed to dry etching and damaged during the process of forming a drain electrode and a source electrode by dry etching. Then, the damage adversely affects the characteristics of the TFT. Since OFF operations of an amorphous oxide TFT are realized by a fully depleted state, the semiconductor channel layer is thin. Therefore, an over-etching process that is employed for amorphous Si-TFTs can hardly be adopted. Thus, techniques of removing the damaged layer by wet etching, using an acidic aqueous solution have been proposed (U.S. Patent Publications US2008/315193A1 and US2011/049508A1 and C.-J. Kim et al., Electrochem. Solid-State Lett. 12 (4), H95-H97 (2009)).

The known techniques disclosed in US2008/315193A1 and C.-J. Kim et al., Electrochem. Solid-State Lett. 12 (4), H95-H97 (2009)) can improve the TFT characteristics by introducing a step of removing the damaged layer of the oxide semiconductor layer by wet etching into a process of manufacturing a channel-etch type TFT, using an oxide semiconductor. However, an operation of uniformly removing the damaged layer that is the uppermost layer having a thickness of several nm at most over the entire area of the glass substrate that extends by several meters is an extremely difficult one. Then, the uniformity of the film thickness of the semiconductor layer of a TFT obtained by such a technique is unsatisfactory. Therefore, there is a demand for channel-etch type TFTs having a semiconductor layer representing a uniform film thickness.

Meanwhile, US2011/049508A1 discloses a technique of arranging a sacrificial layer on the semiconductor channel layer, the sacrificial layer representing an etching rate greater than the semiconductor channel layer, and realizing a uniform film thickness by means of selectivity of etching rate. Introducing a sacrificial layer itself is a known technical idea. The sacrificial layer is left unremoved because it is sandwiched between the semiconductor channel layer and the source/drain electrodes and turns to be a series resistance component of the TFT to consequently reduce the drive force of the TFT. Therefore, the resistivity of the sacrificial layer needs to be sufficiently low. In US2011/049508A1, an oxide semiconductor layer that differs from the semiconductor channel layer in terms of component elements and composition is used as sacrificial layer. However, the component elements and the composition of the sacrificial layer that can give rise to a large difference of wet etching rate do not necessarily ensure a low resistivity. Furthermore, a step using a sputtering target and a sputtering chamber different from those for the channel layer needs to be added in order to deposit an oxide semiconductor layer having different component elements and a different composition on the semiconductor channel layer. Such an arrangement of an additional step can be detrimental to the use of channel-etch type TFTs with the aim of reducing the number of manufacturing steps relative to etch-stopper type TFTs. Thus, the technique disclosed in US2011/049508A1 is accompanied by these two technical problems to be solved.

In view of the above-identified problems, an object of the present invention is to provide a channel-etch type TFT representing an improved uniformity in terms of film thickness of the semiconductor layer and TFT characteristics without entailing any increase of manufacturing cost and degradation of TFT performance and a method of manufacturing such a TFT.

### SUMMARY OF THE INVENTION

In a first aspect of the present invention, the above object is achieved by providing a channel-etch type thin film transistor having a gate electrode, a gate insulating layer, a channel layer made of an oxide semiconductor, a source electrode and a drain electrode on a substrate, wherein the channel layer is electrically connected with the source electrode and the drain electrode by way of a sacrificial layer, the sacrificial layer is made of an oxide containing In, Zn and Ga, the etching rate of the sacrificial layer is higher than the etching rate of the channel layer, and the resistivity of the sacrificial layer is not greater than 3.38×10⁷ Ωcm.

In a second aspect of the present invention, there is provided a method of manufacturing a channel-etch type thin film transistor including steps of: forming a gate electrode on a substrate; forming a gate insulating layer on the gate electrode; forming a channel layer made of an oxide semiconductor on the gate insulating layer; forming a sacrificial layer made of an oxide containing In, Zn and Ga on the channel layer, the sacrificial layer representing an etching rate greater than the channel layer and a resistivity not greater than 3.38×10⁷ Ωcm; forming a drain electrode and a source electrode on the sacrificial layer; and removing the sacrificial layer exposed between the drain electrode and the source electrode by means of wet etching to expose the channel layer. The above steps are sequentially carried out in the above-listed order.

In a third aspect of the present invention, there is provided a method of manufacturing a channel-etch type thin film transistor including steps of: forming a channel layer made of an oxide semiconductor on a substrate; forming a sacrificial layer made of an oxide containing In, Zn and Ga on the channel layer, the sacrificial layer representing an etching rate greater than the channel layer; forming a drain electrode and a source electrode on the sacrificial layer; removing the sacrificial layer exposed between the drain electrode and the source electrode by means of wet etching to expose the channel layer; forming a gate insulating layer on the drain electrode, the source electrode and the channel layer; and forming a gate electrode on the gate insulating layer. The above steps are sequentially carried out in the above-listed order.

Thus, a channel-etch type TFT using an oxide semiconductor for the channel layer thereof according to the present invention represents an improved uniformity in terms of film thickness of the channel layer after wet etching as well as TFT characteristics with an improved uniformity thereof. When an oxide semiconductor containing In, Ga and Zn like the sacrificial layer is used for the channel layer (i.e. with the same component elements and the same composition as those of the sacrificial layer), the channel layer and the sacrificial layer can be formed successively by means of the same apparatus to achieve a high manufacturing efficiency. As a result, the manufacturing cost can be suppressed. Since a sacrificial layer containing In, Ga and Zn which was deposited with a low sputtering power density represents a low resistivity and hence does not raise the series resistance of the TFT to allow the TFT to maintain a high drive force. Furthermore, the low resistivity of the sacrificial layer by turn reduces the contact resistance of the channel layer with the source and drain electrodes. Thus, the present invention can provide a channel-etch type TFT representing excellent TFT characteristics with a high degree of reproducibility, uniformity and efficiency.

Further features of the present invention will become apparent from the following description of exemplary embodiments with reference to the attached drawings.

### BRIEF DESCRIPTION OF THE DRAWINGS

FIGS. 1A, 1B, 1C, 1D, 1E, 1F, 1G and 1H are schematic cross-sectional views of channel-etch type TFT according to an embodiment of the present invention, illustrating exemplar manufacturing steps thereof.

FIGS. 2A and 2B are schematic cross-sectional views of channel-etch type TFT according to another embodiment of the present invention, illustrating the configuration thereof.

FIG. 3 is a graph illustrating the relationship between the DC sputtering power required for forming a film of an oxide containing In, Ga and Zn and the etching rate of the film to be obtained.

FIG. 4 is a graph illustrating the relationship between the composition of an oxide containing In, Ga and Zn and the etching rate of the film to be obtained.

### DESCRIPTION OF THE EMBODIMENTS

Preferred embodiments of the present invention will now be described in detail in accordance with the accompanying drawings.

A channel-etch type thin film transistor (TFT) and a method of manufacturing the same according to the present invention will be described below in greater detail.

A channel-etch type TFT according to the present invention includes a gate electrode, a gate insulating layer, a channel layer, a source electrode and a drain electrode, which are basic components of TFT, and the channel layer are electrically connected with the source electrode and the drain electrode by way of a sacrificial layer. Such a sacrificial layer is characterized by being made of an oxide containing In, Zn and Ga (In—Ga—Zn—O) and representing an etching rate higher than the channel layer.

A channel-etch type TFT according to the present invention is applicable to all of the bottom gate type, the top gate type and the double gate type and the method of manufacturing it varies depending on the gate position. However, regardless of type, forming a channel layer that is made of an oxide semiconductor, forming a sacrificial layer and then a source electrode and a drain electrode thereon and wet etching the sacrificial layer to expose the channel layer are common to all the variations of the method.

In the case of a bottom gate type TFT, the manufacturing steps include:

1) a gate electrode forming step of forming a gate electrode on a substrate;
2) a gate insulating layer forming step of forming a gate insulating layer on the gate electrode;
3) a channel layer forming step of forming a channel layer made of an oxide semiconductor on the gate insulating layer;
4) a sacrificial layer forming step of forming a sacrificial layer made of an oxide containing In, Zn and Ga and representing an etching rate higher than the channel layer on the channel layer;
5) an electrode forming step of forming a drain electrode and a source electrode on the sacrificial layer; and
6) a wet etching step of wet etching the sacrificial layer exposed between the drain electrode and the source electrode to expose the channel layer.

In the case of a top gate type TFT, the manufacturing steps include:

1) a channel layer forming step of forming a channel layer made of an oxide semiconductor on a substrate;
2) a sacrificial layer forming step of forming a sacrificial layer made of an oxide containing In, Zn and Ga and representing an etching rate higher than the channel layer on the channel layer;
3) an electrode forming step of forming a drain electrode and a source electrode on the sacrificial layer;
4) a wet etching step of wet etching the sacrificial layer exposed between the drain electrode and the source electrode to expose the channel layer;
5) a gate insulating layer forming step of forming a gate insulating layer on the drain electrode, the source electrode and the channel layer; and
6) a gate electrode forming step of forming a gate electrode on the gate insulating layer.

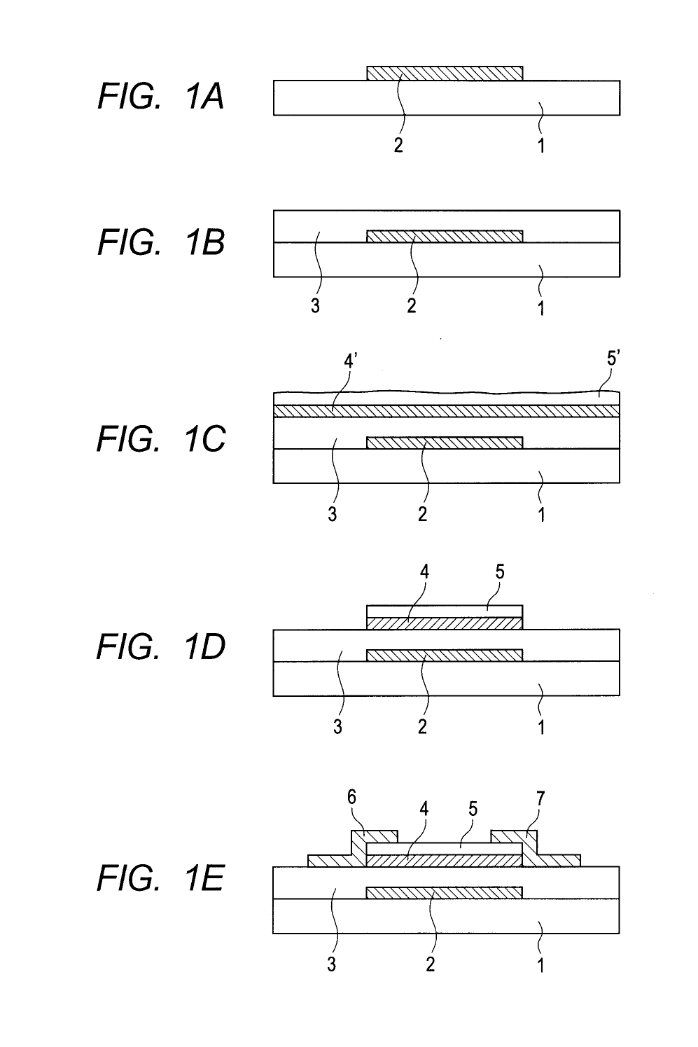

FIGS. 1A through 1H are schematic cross-sectional views of an embodiment of channel-etch type TFT according to the present invention, which is a bottom gate type TFT, illustrating exemplar manufacturing steps thereof. As illustrated in FIG. 1F, the TFT of this embodiment has a structure formed by sequentially laying a gate electrode 2, a gate insulating layer 3, a channel layer 4, a sacrificial layer 5, a drain electrode 6 and a source electrode 7 on a substrate 1.

The substrate 1 is an insulating substrate. More specifically, the substrate 1 may be a glass substrate or made of a film or a thin plate of an organic material such as polyethylene terephthalate (PET), polyethylene naphthalate (PEN), polyimide or polycarbonate. A stainless substrate coated with an insulating layer on the surface may alternatively be used.

Firstly, a conductive film for forming a gate electrode 2 is deposited on a substrate 1. The material of the conductive film may be an electrically conductive metal oxide (MO_{X}, where M is a metal element). Alternatively, an electrically conductive organic material such as polyethylene dioxythiophene doped with polystyrene sulfonic acid (PEDOT: PSS) may be used. The film may be a single layer film or a multilayer film having two or more than two layers. A film forming technique such as a vapor phase method selected from chemical vapor phase deposition (CVD), sputtering, pulse laser evaporation and electron beam evaporation may preferably be employed. After the film formation, a gate electrode 2 is formed by patterning the conductive film (FIG. 1A). Note, however, that film forming techniques are by no means limited to the above-described ones and additionally include spin coating, spray coating, ink jet printing and screen printing.

Then, a gate insulating layer 3 is deposited on the gate electrode 2 (FIG. 1B). The material of the gate insulating layer 3 may be an inorganic material selected from oxides, carbides, nitrides, fluorides and mixtures of any of them or may alternatively be an organic material. A metal oxide film containing at least a metal element is preferably employed. Preferable metal oxides that can be used for the gate insulating layer 3 include SiO₂, Al₂O₃, Ga₂O₃, In₂O₃, MgO, CaO, SrO, BaO and ZnO as well as Nb₂O₅, Ta₂O₅, TiO₂, ZrO₂, HfO₂, CeO₂, Li₂O, Na₂O, K₂O, Rb₂O, Sc₂O₃, Y₂O₃, La₂O₃, Nd₂O₃, Sm₂O₃, Gd₂O₃, Dy₂O₃, Er₂O₃ and Yb₂O₃. Additionally, metal compounds that can be used for the gate insulating layer 3 include metal nitrides (MN_{X}, where M is a metal element) and metal oxynitrides (MOₓN_{y}, where M is a metal element). Furthermore, organic insulating materials such as PET, PEN, polyimide, polycarbonate and parylene can be used for the gate insulating layer 3. The gate insulating layer 3 may be a single layer or a multilayer having two or more than two sub-layers. A film forming technique such as a vapor phase method selected from CVD, sputtering, pulse laser evaporation and electron beam evaporation may preferably be employed. Note, however, that the film forming techniques that can be used for the purpose of the present invention are by no means limited to the above-described ones and additionally include spin coating, spray coating, ink jet printing and screen printing.

Subsequently, an oxide semiconductor layer 4′ that becomes a channel layer is formed on the gate insulating layer 3 by deposition. Preferable oxide semiconductors include oxides containing ZnO as principal component, oxides containing In₂O₃ as principal component, oxides containing Ga₂O₃ as principal component and oxides having an complex oxide containing two or more than two of such oxides as principal component. Oxides containing In₂O₃ and ZnO, when put together, by not less than a half of the entire oxide in terms of molar ratio are particularly preferable. Since the sacrificial layer is formed by using In—Ga—Zn—O according to the present invention, the oxide semiconductor layer 4′ is preferably formed also by using In—Ga—Zn—O because the oxide semiconductor layer 4′ and the layer that becomes sacrificial layer can be produced successively. The oxide semiconductor layer 4′ may contain one or more than one oxide semiconductors such as SnO₂ and/or TiO₂ among others. A vapor phase method selected from CVD, sputtering, pulse laser evaporation and electron beam evaporation may preferably be employed as film forming technique. Note, however, that film forming techniques that can be used for forming the oxide semiconductor layer 4′ are by no means limited to the above-described ones and additionally include spin coating, spray coating, ink jet printing and screen printing.

The film thickness of the oxide semiconductor layer 4′ is determined as a function of the oxide semiconductor material of the layer. Generally, the film thickness is preferably between 0.5 and 100 nm. Particularly, when In—Ga—Zn—O is employed, the film thickness is preferably between 10 and 70 nm because such a thickness can provide excellent operations and most preferably between 10 and 50 nm because the TFT can be turned into an off state with ease with such a film thickness.

Thereafter, a layer 5′ that becomes the sacrificial layer is formed on the oxide semiconductor layer 4′ by deposition (FIG. 1C). The layer 5′ that becomes the sacrificial layer contains In—Ga—Zn—O. More specifically, the layer 5′ is made of a mixture of ZnO, In₂O₃ and Ga₂O₃.

Preferably, the oxide semiconductor layer 4′ and the layer 5′ that becomes the sacrificial layer have common component elements. Furthermore, preferably, the oxide semiconductor layer 4′ and the layer 5′ that becomes the sacrificial layer have the same composition. For the purpose of the present invention, “having the same composition” includes “having the same composition with different composition ratios”. Thus, the oxide semiconductor layer 4′ and the layer 5′ that becomes the sacrificial layer may represent different composition ratios provided that they have the same composition. Then, the oxide semiconductor layer 4′ and the layer 5′ that becomes the sacrificial layer are allowed to have one or more than one elements that are not common to them so long as the their etching characteristics are not affected significantly (for example, the etching rate of either of them is not greater than twice of the other's etching rate).

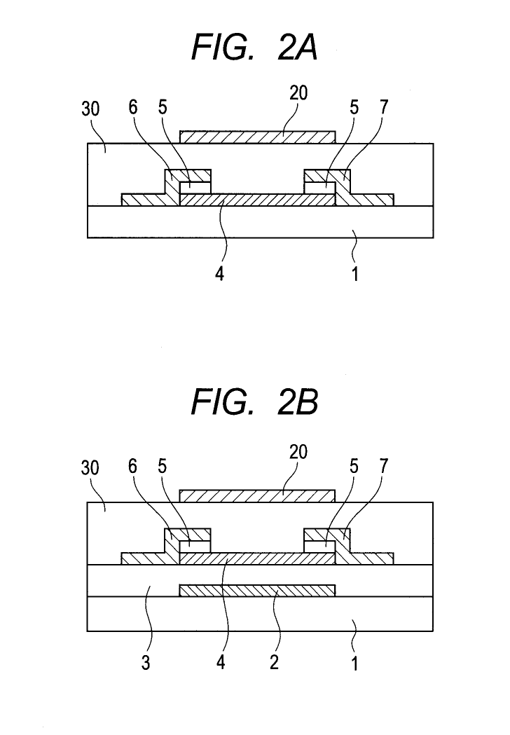

The etching rate can be controlled by changing the DC sputtering power requirement when deposition of In—Ga—Zn—O. FIG. 3 illustrates a graph illustrating the relationship between the sputtering power (power density) required for depositing In—Ga—Zn—O and the etching rate of the film to be obtained. Presumably, the two layers represent respective etching rates that are different from each other when their In—Ga—Zn—O densities (atomic mass densities) and/or their surface areas differ from each other. When the sputtering power density is low, the atomic mass density of the In—Ga—Zn—O layer is low, whereby the etching rate consequently falls in the wet etching process.

TABLE 1

| | | Distance | | |
|---|---|---|---|---|
| | | between | | |
| | | target and | | Etching |
| DC Power | Pressure | substrate | Density | rate |
| (W) | (Pa) | (mm) | (mg/cm³) | (nm/sec) |
| 300 | 1.0 | 85 | 5325.8 | 136 |
| 800 | 1.0 | 85 | 5684.7 | 30.6 |
| 2000 | 1.0 | 85 | 6003.9 | 4.82 |
| 800 | 0.5 | 85 | 6010.5 | 4.31 |
| 800 | 1.0 | 100 | 5872.0 | 13.4 |

As will be seen from Table 1, the density of In—Ga—Zn—O can be controlled appropriately by the sputtering power, the film forming pressure for sputtering, the distance between the sputtering target and the substrate etc. as parameters. The etching rate can be made to vary within a range of tens of several times as a function of the density of In—Ga—Zn—O.

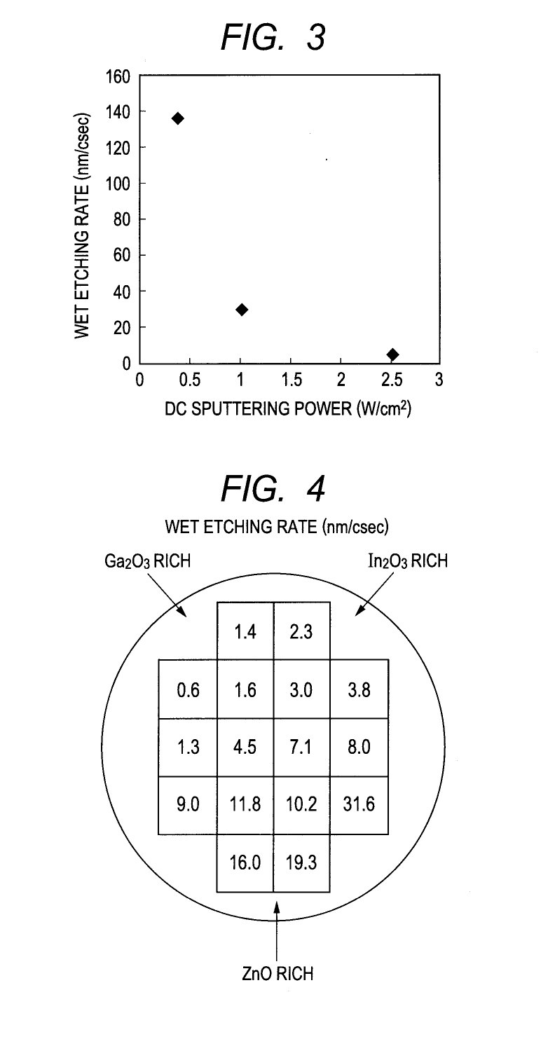

FIG. 4 is a graph illustrating the results obtained by observing the etching rate of a sample whose In, Ga and Zn composition changes continuously on a single substrate. The etching rate of In—Ga—Zn—O tends to fall as the composition ratio of Ga increases relative to that of In or Zn. An In—Ga—Zn—O layer 5′ representing an etching rate higher than the oxide semiconductor layer 4′ can be obtained by utilizing this relationship.

The In—Ga—Zn—O layer 5′ may be a single layer film or a multilayer film having a plurality of film layers. The resistivity of the In—Ga—Zn—O layer 5′ falls as the sputtering power density is lowered. Making the In—Ga—Zn—O layer 5′ represent a low resistivity provides an advantage of improving the electric contact between the channel layer 4 and the drain electrode 7 and the source electrode 8. In other words, the series resistance component is reduced and, at the same time, the contact resistance of the channel layer 4 with the drain electrode 7 and the source electrode 8 is also reduced.

A vapor phase method selected from CVD, sputtering, pulse laser evaporation and electron beam evaporation may preferably be employed as film forming technique for forming the In—Ga—Zn—O layer 5′. Note, however, that film forming techniques that can be used for forming the In—Ga—Zn—O layer 5′ are by no means limited to the above-described ones and additionally include spin coating, spray coating, ink jet printing and screen printing.

Subsequently, the channel layer 4 and the sacrificial layer 5 are formed by patterning the oxide semiconductor layer 4′ and the In—Ga—Zn—O layer 5′ (FIG. 1D). If necessary, a plasma treatment and/or a heat treatment may be conducted after the patterning operation. For example, a plasma treatment using Ar, O₂, N₂O, N₂, H_{z}, H₂O, CF₄, Cl₂ or a mixture gas of any of the listed gaseous substances may be conducted. Additionally, a heat treatment may be conducted in an atmosphere selected from dry air, N₂, O₂, H₂O, H₂ or a mixture gas of any of the listed gaseous substances may be conducted.

Thereafter, a conductive film is formed on the channel layer 4 and the sacrificial layer 5 by deposition and the drain electrode 6 and the source electrode 7 are formed by patterning the conductive film (FIG. 1E). A material selected from metals, electrically conductive metal oxides (MOₓ, where M is a metal element), metal oxynitrides (MOₓN_{y}, where M is a metal element) and electrically conductive organic materials may be used for forming the conductive film. The conductive film may be a single layer film or a multilayer film having a plurality of film layers. A vapor phase method selected from CVD, sputtering, pulse laser evaporation and electron beam evaporation may preferably be employed as film forming technique for forming the conductive film. Note, however, that film forming techniques are by no means limited to the above-described ones and additionally include spin coating, spray coating, ink jet printing and screen printing. If necessary, a plasma treatment and/or a heat treatment may be conducted after the patterning operation.

Then, the sacrificial layer 5 is wet etched to expose the channel layer 4 between the drain electrode 6 and the source electrode 7 (FIG. 1F). An acidic solution of acetic acid, hydrochloric acid, perchloric acid, hydrofluoric acid, nitric acid, phosphoric acid or the like can be used as etching solution to be used for the wet etching operation. Alternatively, a basic solution containing ammonia, tetramethylammonium or the like may be used for the wet etching operation. The uniformity of the film thickness of the channel layer 4 after the etching operation can be improved by adopting a large value for the etching selectivity of the sacrificial layer 5 and that of the channel layer 4. The wet etching of the sacrificial layer 5 is considered to be an isotropic etching operation. Side etching of the sacrificial layer 5 in transversal directions of the sacrificial layer 5 proceeds. To prevent side etching, a wet etching solution for wet etching the drain electrode 6 and the source electrode 7 simultaneously with the sacrificial layer 5 may be employed. For example, an aqueous solution of ammonia or a mixture solution of phosphoric acid and nitric acid may be used as wet etching solution for wet etching Mo and an oxide semiconductor simultaneously. The surfaces of the electrodes may be treated to facilitate the etching operation. For example, if the electrodes are Mo electrodes, Mo oxide may be formed on the surfaces of the electrodes by means of an oxygen plasma treatment and/or a heat treatment so that both the Mo oxide and the oxide semiconductor may be dissolved by acid such as hydrochloric acid. If necessary, a plasma treatment and/or a heat treatment may be conducted after the above steps.

Thus, the manufacturing steps for manufacturing a bottom gate type TFT are described above.

A TFT according to the present invention may be formed by further adding an insulating layer, a protection layer, an electrode layer and/or a semiconductor layer.

FIG. 1G illustrates an arrangement where a first protection layer 8 and a second protection layer 9 are additionally laid on a TFT obtained by way of the above-described steps. SiO₂, SiON, SiN or polyimide is preferably employed for the protection layers 8, 9.

FIG. 1H illustrates a state where contact holes 10 are formed in the protection layers 8, 9 to establish electric contact with the drain electrode 6 and the source electrode 7 respectively.

A semiconductor device such as a light receiving element, a light emitting element, a semiconductor memory or a semiconductor logic circuit may be formed on a TFT according to the present invention to make it functionally operate for a sensor or a display. Of course, conversely, a TFT according to the present invention may be formed on such a semiconductor device to make it operate for a sensor or a display.

Now, the wet etching rate and the film thickness of the channel layer 4 and those of the sacrificial layer 5 that make a TFT according to the present invention particularly advantageous will be described below.

According to the present invention, the variances in the film thickness of the channel layer 4 become remarkable as a result of introducing the sacrificial layer 5 unless the etching rate of the sacrificial layer 5 is made high relative to that of the channel layer 4. The quotient obtained by dividing the wet etching rate of the sacrificial layer 5 by the wet etching rate of the channel layer 4 is expressed by R (the ratio of the wet etching rates). The variances in the film thickness of the channel layer 4 after introducing the sacrificial layer 5 are to be reduced to 1/R of the variances in the film thickness of the channel layer 4 of the TFT after the wet etching. Thus, a large value is desirable for R. The value of R is preferably not less than 2 because such a value makes material selection easy for the channel layer 4 and the sacrificial layer 5. When In—Ga—Zn—O is adopted as the oxide semiconductor of the channel layer 4, the value of R is preferably not less than 4 because such a value allows In—Ga—Zn—O to be prepared with small sputtering power as seen from FIG. 3. More preferably, the value of R is not less than 10 because such a value improves the uniformity of film thickness by two digits or more, although then the use of a semiconductor layer representing a small composition ratio for Ga becomes difficult.

The allowable smallest film thickness of the sacrificial layer 5 may vary depending on the material of the sacrificial layer and the conditions for dry etching the drain electrode 6 and the source electrode 7. When In—Ga—Zn—O is employed for the channel layer 4, the depth of the damage due to dry etching in an experiment was about 5 nm when observed through a transmission electron microscope. Therefore, the film thickness of the sacrificial layer 5 is preferably not less than 5 nm. On the other hand, the upper limit of the film thickness of the sacrificial layer is preferably not more than 1,000 nm, which is of a magnitude similar to the channel length, in view of side etching that takes place when wet etching the sacrificial layer 5. Thus, for the purpose of the present invention, the film thickness of the sacrificial layer 5 is preferably not less than 5 nm and not more than 1,000 nm. More preferably, the film thickness of the sacrificial layer 5 is not more than 600 nm, which is less than equivalent to the film thickness of the protection layers, when the coating effect at the time of forming the protection layers by deposition is taken into consideration. Most preferably, the film thickness of the sacrificial layer 5 is not more than 100 nm in order make the film forming time for the sacrificial layer 5 subsequently equal to the film forming time for the semiconductor layer.

As illustrated in FIG. 1F, the sacrificial layer is left between the drain electrode 6 and the source electrode 7 and the channel layer 4 after the wet etching operation. When the resistance of the sacrificial layer 5 is high, the TFT characteristics are adversely affected. The resistance of the sacrificial layer 5 tends to affect the TFT characteristics when the channel length is small. Imagine a TFT having a channel length of 3 μm. Assume that the distance by which the drain electrode 6 overlaps the semiconductor and the distance by which the source electrode 7 overlaps the semiconductor are equally 10 μm, the channel width is W μm and the film thickness and the resistivity of the sacrificial layer are respectively 5 nm and R_{G}Ω cm. Also assume that the film thickness of the gate insulating layer is 200 nm, the dielectric constant of the material of the gate insulating layer is 4 and the field-effect mobility is 10 m²/Vs. Then, let us examine instances where the value V_{G-th} of differences obtained by subtracting the threshold voltage Vₜₕ from the gate voltage V_{G} during operation are 15, 10, 5 and 1 V respectively. The semiconductor resistances in the linear region can be estimated by means of gradual channel approximation. They are the quotients obtained by dividing 1.13×10⁶, 1.69×10⁶, 3.39×10⁶ and 1.69×10⁷ by W respectively according to the values of V_{G-th}. The resistance of the sacrificial layer is the quotient obtained by dividing 5R_{G} by W. As a result of calculating the value of R_{G} under the condition that the resistance of the sacrificial layer is not greater than ten times of the resistance of the semiconductor in an on state, R_{G} is preferably not greater than 3.38×10⁷ Ωcm when the TFT is operable if V_{G-th} is not less than 1V, more preferably not greater than 6.78×10⁶ Ωcm when the TFT is operable if V_{G-th} is not less than 5 V, more preferably not greater than 3.38×10⁶ Ωcm when the TFT is operable if V_{G-th} is not less than 10V and furthermore preferably not greater than 2.26×10⁶ Ωcm when the TFT is operable if V_{G-th} is not less than 15 V.

Now, a top gate type TFT and a double gate type TFT will be illustrated as examples of channel-etch type transistor according to the present invention.

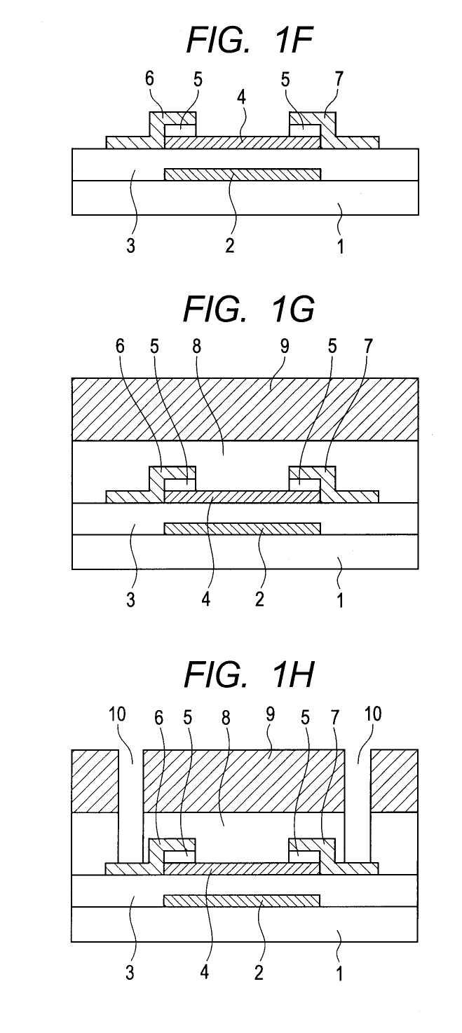

The method of manufacturing a top gate type TFT partly differs from the method of manufacturing a bottom gate type TFT described above by referring to FIGS. 1A through 1H. More specifically, as illustrated in FIG. 2A, a top gate type TFT has a structure formed by sequentially laying a channel layer 4, a sacrificial layer 5, a drain electrode 6, a source electrode 7, an upper gate insulating layer 30 and an upper gate electrode 20 on a substrate 1. Each of the layers can be formed just like their counterparts of a bottom gate type TFT and the upper gate insulating layer 30 and the upper gate electrode 20 may well be formed respectively just like the gate insulating layer 3 the gate electrode 2 of a bottom gate type TFT.

A double gate type TFT, on the other hand, has a structure formed by sequentially laying a gate electrode 2, a gate insulating layer 3, a channel layer 4, a sacrificial layer 5, a drain electrode 6, a source electrode 7, an upper gate insulating layer 30 and an upper gate electrode 20 on a substrate 1 as illustrated in FIG. 2B. Each of the layers can be formed just like their counterparts of a bottom gate type TFT and a top gate type TFT. A double gate type TFT has two date electrodes 2, 20 and the electric potential of each of the gate electrodes can be freely controlled. There are instances where the gate electrodes are operated as floating gate electrodes. The TFT can be driven by using the two gate electrodes, only the bottom gate electrode or only the top gate electrode. Additionally, the gate electrodes can be used as light shielding layers.

### EXAMPLES

### Example 1

A bottom gate, channel-etch type TFT was prepared by following the steps illustrated in FIGS. 1A through 1H. Now, each of the steps will be described below.

A glass substrate (1737, available from Corning) was used for the substrate 1. The glass substrate had a thickness of 0.5 mm. Firstly a 100 nm-thick Mo thin film was formed on the substrate 1 by means of DC magnetron sputtering in an atmosphere of Ar gas. Then, the deposited Mo thin film was micro-processed to produce a gate electrode 2 by means of photolithography and dry etching (FIG. 1A).

Thereafter, a 200 nm-thick SiO₂ thin film was formed as a gate insulating layer 3 on the gate electrode 2 by plasma CVD (FIG. 1B).

Subsequently, a 40 nm-thick In—Ga—Zn—O thin film (oxide semiconductor layer 4′) was formed on the gate insulating layer 3 by means of DC magnetron sputtering with a DC power supply rate of 3.7 W/cm². The In—Ga—Zn—O thin film formed in this way was amorphous and the composition ratio of In:Ga:Zn:O was about 1:1:1:4.

Then, a 30 nm-thick In—Ga—Zn—O thin film 5′ was formed on the oxide semiconductor layer 4′ by means of DC magnetron sputtering with a DC power supply rate of 0.38 W/cm² (FIG. 1C). the In—Ga—Zn—O thin film formed in this way was amorphous and the composition ratio of In:Ga:Zn:O was about 1:1:1:4. As seen from FIG. 3, an In—Ga—Zn—O thin film formed with a low power supply rate represents a high wet etching rate. The reason for this is conceivably because such a thin film has a large surface area. Then, the above-described two layers of In—Ga—Zn—O thin films were subjected to a patterning operation by means of photolithography and wet etching using hydrochloric acid to produce a semiconductor layer 4 and a sacrificial layer 5 (FIG. 1D).

Thereafter, a 200 nm-thick Mo thin film was formed on the sacrificial layer 5 by DC magnetron sputtering and micro-processed to produce a drain electrode 6 and a source electrode 7 by means of photolithography and dry etching (FIG. 1E).

Subsequently, the sacrificial layer 5 was wet etched by using an etching solution prepared by mixing 35% to 37% hydrochloric acid and deionized water to a volume ratio of 1:40 (FIG. 1F).

Thereafter, a 300 nm-thick SiO₂ thin film was formed as a first protection layer 8 on the drain electrode 6 and the source electrode 7 by plasma CVD and then a 300 nm-thick SiON thin film was formed as a second protection layer 9 by plasma CVD (FIG. 1G).

Subsequently, contact holes 10 were formed to establish electric contact with the electrodes by means of buffered hydrofluoric acid (FIG. 1H).

In Comparative Example, a TFT was prepared by following the steps same as the above-described ones except that no sacrificial layer 5 was formed therein.

Table 2 represents the film thickness uniformity of the TFT of Example 1 and that of the TFT of Comparative Example 1 as evaluated by way of the standard deviations σ of the threshold voltage Vₜₕ for them. The standard deviations σ were determined by preparing 13 TFTs for Example 1 and also 13 TFTs for Comparative Example 1.

TABLE 2

| | | Comparative |
|---|---|---|
| | Example 1 | Example 1 |
| Existence or non-existence | Existence | Non-existence |
| sacrificial layer | | |
| Standard deviation σ of | 2.2 V | 4.5 V |
| threshold voltage | | |

As will be clearly understood by seeing Table 2, the value of σ was improved from 4.5V to 2.2V as a result of introducing a sacrificial layer 5. The uniformity of Vₜₕ refers to an improvement of the film thickness uniformity and indicates that the post-wet etching film thickness uniformity of the channel layer 4 can be improved.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-282814, filed Dec. 20, 2010, and Japanese Patent Application No. 2011-244061, filed Nov. 8, 2011, which are hereby incorporated by reference herein in their entirety.

What is claimed is:

1. A channel-etch type thin film transistor having a gate electrode, a gate insulating layer, a channel layer made of an oxide semiconductor, a source electrode and a drain electrode on a substrate,
the channel layer being electrically connected with the source electrode and the drain electrode by way of a sacrificial layer,
the sacrificial layer being made of an oxide containing In, Zn and Ga, the etching rate of the sacrificial layer being higher than the etching rate of the channel layer, and
the resistivity of the sacrificial layer being not greater than 3.38×10⁷ Ωcm.

2. The channel-etch type thin film transistor according to claim 1, wherein the ratio of the etching rate of the channel layer to the etching rate of the sacrificial layer is not less than 2.

3. The channel-etch type thin film transistor according to claim 1, wherein the film thickness of the sacrificial layer is not less than 5 nm and not more than 1,000 nm.

4. The channel-etch type thin film transistor according to claim 1, wherein the channel layer is made of an oxide containing at least one selected from In, Zn and Ga.

5. The channel-etch type thin film transistor according to claim 1, wherein the channel layer and the sacrificial layer have the same composition.

6. A method of manufacturing a channel-etch type thin film transistor, comprising steps of:
forming a gate electrode on a substrate;
forming a gate insulating layer on the gate electrode;
forming a channel layer made of an oxide semiconductor on the gate insulating layer;
forming a sacrificial layer made of an oxide containing In, Zn and Ga on the channel layer, the sacrificial layer representing an etching rate greater than the channel layer and a resistivity not greater than 3.38×10⁷ Ωcm;
forming a drain electrode and a source electrode on the sacrificial layer; and
removing the sacrificial layer exposed between the drain electrode and the source electrode by means of wet etching to expose the channel layer,
the above steps being sequentially carried out in the listed order.

7. A method of manufacturing a channel-etch type thin film transistor, comprising steps of:
forming a channel layer made of an oxide semiconductor on a substrate;
forming a sacrificial layer made of an oxide containing In, Zn and Ga on the channel layer, the sacrificial layer representing an etching rate greater than the channel layer;
forming a drain electrode and a source electrode on the sacrificial layer;
removing the sacrificial layer exposed between the drain electrode and the source electrode by means of wet etching to expose the channel layer;
forming a gate insulating layer on the drain electrode, the source electrode and the channel layer; and
forming a gate electrode on the gate insulating layer,
the above steps being sequentially carried out in the listed order.
